(19) United States
(12) Patent Application Publication
(10) Pub. No.: US 2022/0020875 A1
(43) Pub. Date: Jan. 20, 2022

(54) SEMICONDUCTOR DEVICE

(71) Applicants: Hyundai Motor Company, Seoul (KR); KIA Motors Corporation, Seoul (KR)

(72) Inventor: JongSeok LEE, Suwon-si (KR)

(73) Assignees: Hyundai Motor Company, Seoul (KR); Kia Motors Corporation, Seoul (KR)

(21) Appl. No.: 17/103,017

(22) Filed: Nov. 24, 2020

(30) Foreign Application Priority Data
Jul. 20, 2020 (KR) 10-2020-0089620

(51) Int. Cl. H01L 29/78; H01L 29/10

(52) U.S. Cl. CPC H01L 29/7802; H01L 29/1037

(57) ABSTRACT

A semiconductor device is provided. The semiconductor may include: a substrate; an N− epitaxial layer disposed on the substrate; P areas positioned on the N− epitaxial layer and spaced apart from each other with a channel therebetween; and N+ areas positioned inside the P areas, wherein the channel includes: a trench area in which the P areas are partially etched so that the N+ areas face each other; and a planar area in which the P areas are not etched to face each other.

### CROSS-REFERENCE TO RELATED APPLICATION

This application claims priority to and benefits of Korean Patent Application No. 10-2020-0089620, filed on Jul. 20, 2020, the entire contents of which are incorporated herein by reference.

### TECHNICAL FIELD

The present disclosure relates to a semiconductor device, and specifically relates to a semiconductor device in which a trench gate device and a planar gate device are combined to improve current density.

### BACKGROUND

In recent years, depending on a large-scale and large-capacity trend of application devices, a need for power semiconductor devices having a high breakdown voltage, a high current, and a high-speed switching characteristic has emerged.

Such a power semiconductor device particularly requires low on-resistance or a low saturation voltage in order to reduce a power loss in a conduction state while allowing a very large current to flow. In addition, a characteristic of being capable of withstanding a reverse high voltage of a PN junction applied to opposite ends of the power semiconductor device, that is, a high breakdown voltage characteristic, is basically required in an off state or when a switch is turned off.

In manufacturing a power semiconductor device, concentration and thickness of an epi region or a drift region of a raw material used are determined depending on a rated voltage of the semiconductor device. An increase in a surface electric field at an interface between a semiconductor and a dielectric must be minimized by appropriately dispersing an electric field induced by expansion of a depletion layer in a reverse bias mode of the pn junction by appropriately utilizing a pn junction structure, and devices must be designed to withstand an inherent critical electric field of the raw material in breakdown of the power semiconductor device, in order to obtain an appropriate breakdown voltage at a desired level with the concentration and thickness of the raw material required by breakdown voltage theory.

The above information disclosed in this Background section is only for enhancement of understanding of the background of the disclosure, and therefore it may contain information that does not form the prior art that is already known in this country to a person of ordinary skill in the art.

### SUMMARY

The present disclosure provides a semiconductor device with improved current density.

An exemplary embodiment of the present disclosure provides a semiconductor element including: a substrate; an N− epitaxial layer disposed on the substrate; P areas positioned on the N− epitaxial layer and spaced apart from each other with a channel therebetween; and N+ areas positioned inside the P areas, wherein the channel includes: a trench area in which the P areas are partially etched so that the N+ areas face each other; and a planar area in which the P areas are not etched to face each other.

The trench area and the planar area may alternately be disposed with each other.

The semiconductor device may further include the gate electrode disposed to overlap the channel area, and a gate insulating layer configured to insulate the gate electrode from the channel area.

A length of the N− areas in the trench area may be longer than that of the N− areas in the planar area.

The P areas may not be positioned between the N+ and N+ areas facing each other in the trench area.

As described above, the semiconductor device according to an exemplary embodiment of the present disclosure may improve current density by increasing density of channels.

### DRAWINGS

FIG. 1 illustrates a cross-section of a semiconductor device in one form of the present disclosure.

FIG. 2 illustrates a cross-sectional view taken along a line A-A′ of FIG. 1.

FIG. 3 illustrates the device of FIG. 1 from the top.

FIG. 4 stereoscopically illustrates the device in one form of the present disclosure.

FIG. 5 more clearly illustrates a channel region in a cross-section corresponding to that of FIG. 4.

FIG. 6 illustrates a schematic cross-sectional view taken along a line A-A′ of FIG. 5.

FIG. 7 illustrates a cross-sectional view taken along a line B-B′ of FIG. 5.

FIG. 8 illustrates a channel and a current direction formed in a conventional planar gate device.

FIG. 9 illustrates a channel and a current direction formed in a conventional trench gate device.

### DETAILED DESCRIPTION

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

In the drawings, the thicknesses of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

A semiconductor device in some forms of the present disclosure will now be described in detail with reference to drawings.

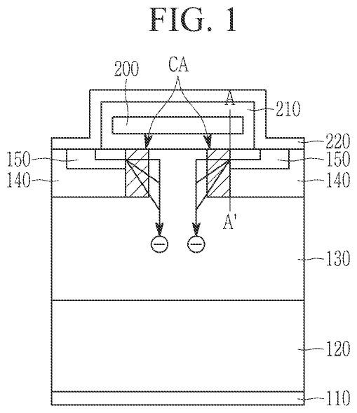

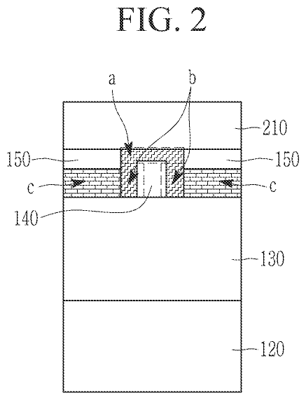

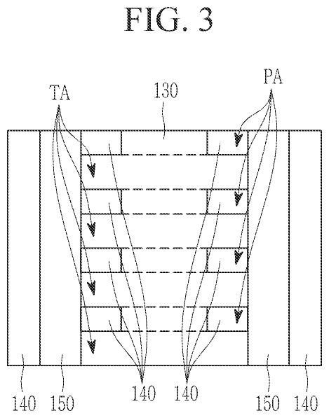

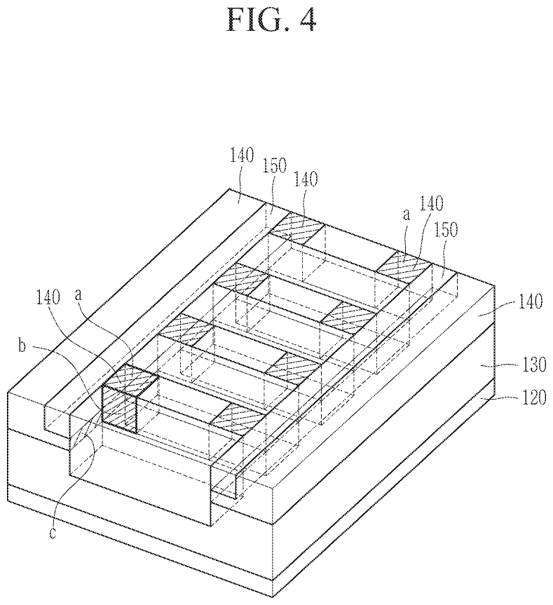

FIG. 1 illustrates a cross-section of a semiconductor device in some forms of the present disclosure. FIG. 2 illustrates a cross-sectional view taken along a line A-A′ of FIG. 1. FIG. 3 illustrates the device of FIG. 1 from the top, and FIG. 4 stereoscopically illustrates the device in some forms of the present disclosure.

Referring to FIG. 1, a drain electrode 110 includes an N+ substrate 120 and an N− epitaxial layer 130 disposed on the N+ substrate 120.

P areas 140 spaced apart from each other are positioned on the N− epitaxial layer 130. N+ areas 150 are positioned within the P areas 140.

A gate electrode 200 may be disposed to be insulated with a gate insulating layer 210, and a source electrode 220 may be disposed on the gate insulating layer 210.

In FIG. 1, a channel area CA of the semiconductor device is illustrated. The channel area CA is formed between the P areas 140 spaced apart from each other, and is formed to have a wider area than that of the existing planar gate structure. This is because a trench gate is formed through local etching in addition to the channel area formed by an existing planar gate. In FIG. 1 the channel area is formed to have a large area, and movement of electrons through the channel area CA is illustrated.

Referring to FIG. 3 and FIG. 4, portions of the P areas 140 are etched between the P areas 140 spaced apart from each other to form a trench. That is, as illustrated in FIG. 3, the semiconductor device in some forms of the present disclosure includes trench areas TA that function like a trench gate device by etching typical planar areas PA and the P areas 140.

That is, in the semiconductor device according to the present exemplary embodiment, a trench is formed by locally etching portions of the P areas 140 in the semiconductor device having a conventional planar gate structure, and a trench gate structure is combined therewith. Therefore, channel density may increase, and current density may be improved.

FIG. 2 distinguishably illustrates channels in a semiconductor device according to the present exemplary embodiment. Referring to FIG. 2, in addition to a channel “a” formed by the conventional planar gate, a channel “b” is formed in the P areas 140 adjacent thereto due to a local trench gate. In addition, a channel “c” around the locally formed trench gate is also added.

Therefore, in the semiconductor device in some forms of the present disclosure, the channels b and c are added compared to the conventional planar gate device, and the channel area is increased as the channels b and c are added compared to the conventional trench gate device.

FIG. 4 illustrates a three-dimensional view of the channel area. Referring to FIG. 4, trench etching was performed between the N+ areas 150 of the conventional planar gate switching device at appropriate intervals as in FIG. 3, thereby securing the additionally generated channels b and c other than the original channel a of the planar gate device.

In the case of the channel b, a width thereof varies according to a depth of the P area 140 that is adjacent to the trench. As a length of the channel c increases, the width of the channel b increases. That is, channel resistance of the channels c and b may have an inversely proportional relationship with each other.

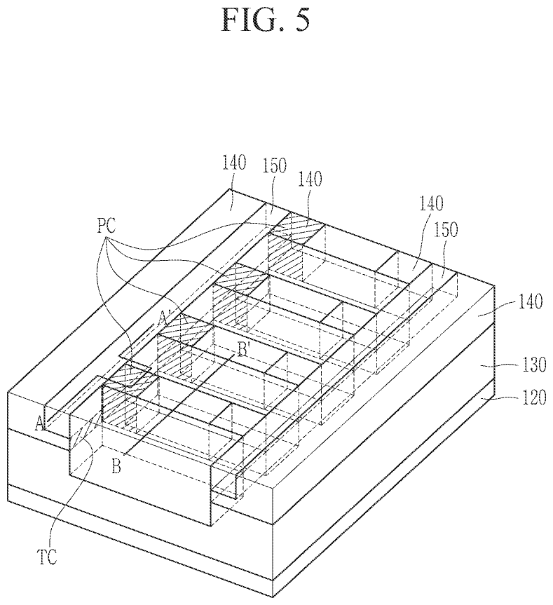

FIG. 5 more clearly illustrates a channel region in a cross-section corresponding to that of FIG. 4. Referring to FIG. 5, a trench channel TC and a planar channel PC are divided.

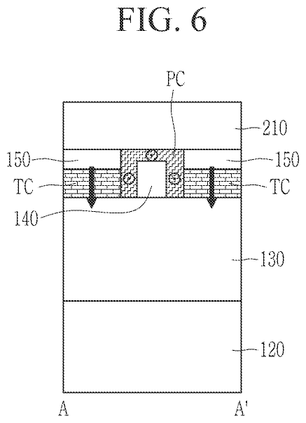

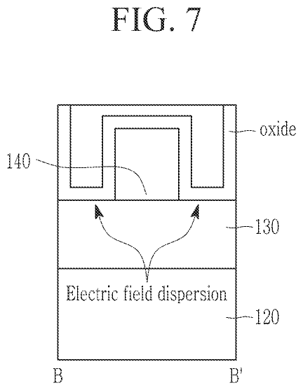

FIG. 6 illustrates a schematic cross-sectional view taken along a line A-A′ of FIG. 5, and FIG. 7 illustrates a cross-sectional view taken along a line B-B′ of FIG. 5.

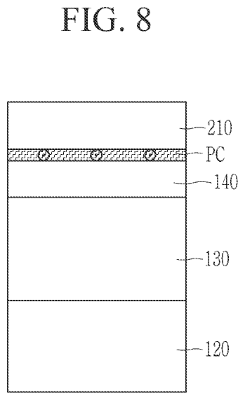

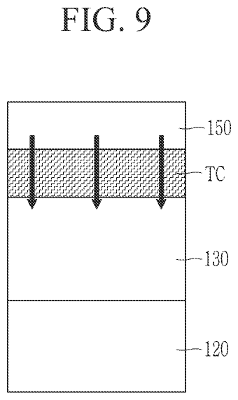

FIG. 8 illustrates a channel and a current direction formed in a conventional planar gate device, and FIG. 9 illustrates a channel and a current direction formed in a conventional trench gate device. Comparing FIG. 6 with FIG. 8 and FIG. 9, it can be seen that the channel density of the semiconductor device according to the present exemplary embodiment has an effect of increasing the channel density by ⅔, i.e., 66%, compared with the conventional trench gate or planar gate technique.

Comparing FIG. 6 and FIG. 8, the density channels formed by trenches is increased (by ⅔) compared with the existing planar gate device, and an additional channel density of ⅔ is added to the existing channel density 1, while the total channel density of 5 becomes 5/3.

Similarly, comparing FIG. 6 and FIG. 9, the density channels formed by trenches is reduced by ⅓ compared with the conventional trench gate device, but when the increase in the channel density formed by adding a planar gate ( 3/3) is added, the total channel density becomes ⅔ of the channel density + 3/3 of the additional channel density, that is, 5/3 of the total channel density.

In addition, as illustrated in FIG. 7, since an electric field concentrated at a lower end of a trench is distributed to several localized trenches, there is a synergistic effect of the breakdown voltage.

As described above, a trench device in some forms of the present disclosure increases the channel density by combining a structure of the planar gate device with the conventional trench gate device and improves a current density of a MOSFET.

Specifically, a channel serving as a trench gate in the planar gate device was used to increase the channel density by locally using a trench etching technique on the top of the device. As a result, an amount of current that is conducted increases, and thus the density of the current that is conducted per unit area is improved. The channel density increases by about 66% compared with the conventional device, and the channel density may increase further as a trench etch width decreases. In addition, reduction of a breakdown voltage due to an electric field concentration at the bottom of the existing trench gate may increase the breakdown voltage because an electric field is dispersed due to the local trench structure of this technology.

While this disclosure has been described in connection with what is presently considered to be practical exemplary embodiments, it is to be understood that the present disclosure is not limited to the disclosed embodiments, but, on the contrary, is intended to cover various modifications and equivalent arrangements included within the spirit and scope greater than or equal to appended claims.

### DESCRIPTION OF SYMBOLS

110: drain electrode

120: N+ substrate

130: N− epitaxial layer

140: P area

150; N+ area

200: gate electrode

210: gate insulating layer

220: source electrode

1. A semiconductor device comprising:
a substrate;
an N− epitaxial layer disposed on the substrate;
P areas positioned on the N− epitaxial layer and spaced apart from each other with a channel therebetween; and
N+ areas positioned inside the P areas,
wherein the channel includes:
a trench area in which the P areas are partially etched so that the N+ areas face each other; and
a planar area in which the P areas are not etched to face each other, wherein the N− epitaxial layer in the trench area and the N− epitaxial layer in the planar area are connected to each other.

2. The semiconductor device of claim 1, wherein the trench area is alternately positioned with the planar area.

3. The semiconductor device of claim 1, wherein the semiconductor device further comprises:
a gate electrode configured to overlap the channel; and
a gate insulating layer configured to insulate the gate electrode from the channel.

4. The semiconductor device of claim 1, wherein a length of the N− epitaxial layer in the trench area is greater than a length of the N− epitaxial layer in the planar area.

5. The semiconductor device of claim 4, wherein the P areas are not positioned between the N+ areas facing each other in the trench area.
